(19) United States
(12) Patent Application Publication
(10) Pub. No.: US 2012/0186604 A1
(43) Pub. Date: Jul. 26, 2012

(54) SEMICONDUCTOR MANUFACTURING APPARATUS AND CLEANING METHOD THEREOF

(75) Inventors: Kensuke Takano, Mie (JP); Shinji Miyazaki, Mie (JP); Ken Ishii, Mie (JP); Takashi Nakao, Mie (JP)

(73) Assignee: KABUSHIKI KAISHA TOSHIBA, Tokyo (JP)

(21) Appl. No.: 13/233,190

(22) Filed: Sep. 15, 2011

(30) Foreign Application Priority Data
Jan. 20, 2011 (JP) 2011-009999

(51) Int. Cl. B08B 5/00; H01L 21/3065

(52) U.S. Cl. 134/1.2; 156/345.26

(57) ABSTRACT

According to one embodiment, a cleaning gas is sealed in a chamber of a semiconductor manufacturing apparatus, and the cleaning gas and deposits adhered in the chamber are reacted with each other to generate a reactive gas. After a predetermined time, the gas is exhausted from the chamber. Then, the chamber is evacuated while the cleaning gas is introduced into the chamber, and the reactive gas concentration contained in an exhausted gas is measured. The reactive gas concentration is compared with a determination value obtained when the deposits are removed from the chamber to determine whether the cleaning is terminated.

### CROSS-REFERENCE TO RELATED APPLICATIONS

This application is based upon and claims the benefit of priority from the prior Japanese Patent Application No. 2011-9999, filed on Jan. 20, 2011; the entire contents of which are incorporated herein by reference.

### FIELD

Embodiments disclosed herein relate generally to a semiconductor manufacturing apparatus and a cleaning method thereof.

### BACKGROUND

In the related art, as a method of removing deposits adhering to the inner surface of a treatment chamber, there is known a semiconductor device manufacturing method which includes, as a single cycle, a process of supplying a halogen-based gas and an oxygen-based gas into a treatment chamber and sealing the gases therein, and a process of evacuating the treatment chamber in vacuum, wherein the single cycle is repeated several times.

However, in recent years, it is required to reduce the use amount of the halogen-based gas for use in removing the deposits adhering to the inner surface of the treatment chamber.

### BRIEF DESCRIPTION OF THE DRAWINGS

FIG. 1 is a diagram schematically illustrating an exemplary configuration of the semiconductor manufacturing apparatus according to a first embodiment;

FIGS. 2A to 2C are diagrams schematically illustrating an exemplary sequence of the cleaning method according to the first embodiment;

FIG. 3 is a diagram illustrating an exemplary reactive gas concentration contained in the evacuated gas;

FIG. 4 is a diagram schematically illustrating an exemplary configuration of the semiconductor manufacturing apparatus according to a second embodiment;

FIG. 5 is a diagram illustrating exemplary film thickness-reactive gas concentration matching information;

FIGS. 6A and 6B are diagrams schematically illustrating an exemplary sequence of the cleaning method according to the second embodiment;

FIG. 7 is a diagram schematically illustrating an exemplary configuration of the semiconductor manufacturing apparatus according to a third embodiment;

FIG. 8 is a diagram schematically illustrating an exemplary sequence of the cleaning method according to the third embodiment;

FIGS. 9A and 9B are diagrams illustrating exemplary actual reactive gas concentration-time information.

### DETAILED DESCRIPTION

In general, according to one embodiment, a cleaning gas is sealed in a chamber of a semiconductor manufacturing apparatus, and the cleaning gas and deposits adhered in the chamber are reacted with each other to generate a reactive gas. After a predetermined time, the gas is exhausted from the chamber. Then, the chamber is evacuated while the cleaning gas is introduced into the chamber so as to make a pressure in the chamber a predetermined value, and the reactive gas concentration contained in an exhausted gas is measured. The reactive gas concentration is compared with a determination value obtained when the deposits are removed from the chamber to determine whether the cleaning is terminated.

Exemplary embodiments of a semiconductor manufacturing apparatus and a cleaning method thereof will be explained below in detail with reference to the accompanying drawings. The present invention is not limited to the following embodiments.

### First Embodiment

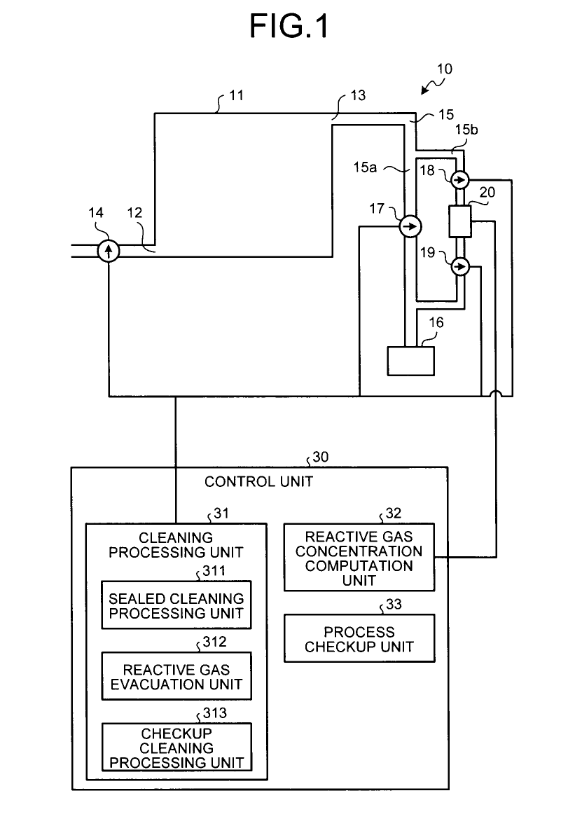

FIG. 1 is a diagram schematically illustrating an exemplary configuration of a semiconductor manufacturing apparatus according to a first embodiment. A semiconductor manufacturing apparatus 10 performs manufacturing of a semiconductor device and has a hermetically sealed chamber 11. In this example, the inside of the chamber 11 is formed using quartz (SiO₂). In addition, it is assumed that a silicon-based film such as a silicon film, a silicon oxide film, and a silicon nitride film is formed inside the chamber 11.

The chamber 11 is provided with a gas inlet 12 for the supply of a treatment gas used to manufacture a semiconductor device or a cleaning gas used to clean the inside of the chamber 11 and a gas outlet 13 for the exhaust of the gas from the chamber 11.

The gas inlet 12 is connected to a gas inlet unit (not illustrated) serving as a supply source of the treatment gas or the cleaning gas through a pipe, and a gas valve 14 for switching on/off the flow of the supplied gas is provided on the pipe. As the cleaning gas for the silicon-based film, for example, a halogen-based gas such as a F₂ gas or a ClF₃ gas may be used.

The gas outlet 13 is connected to a vacuum pump 16 as an evacuation unit through the pipe 15. In addition, the pipe 15 branches into two pipes 15a and 15b, and then combined into a single pipe 15 again. The pipe 15a is provided for exhausting the gas from the chamber 11, and the pipe 15b is provided for detecting a predetermined component in the exhaust gas. The pipe 15a is provided with a gas valve 17 for switching on/off the gas evacuation using the pipe 15a, and the pipe 15b is provided with two gas valves 18 and 19 for switching on/off the gas evacuation using the pipe 15b. In addition, a gas composition detection unit 20 for detecting a predetermined component in the exhaust gas is provided between the two gas valves 18 and 19 of the pipe 15b. In the present embodiment, the gas composition detection unit 20 has a configuration capable of sensing the reactive gas generated by the reaction between deposits adhering to the inner surface of the chamber 11 and the cleaning gas during the cleaning, and performing quantitative analysis thereon. For example, a non-dispersive infrared analysis device (hereinafter, referred to as an NDIR) or a gas mass flow sensor may be used.

In addition, the semiconductor manufacturing apparatus 10 has a control unit 30 for controlling treatment performed in the chamber 11. Hereinafter, a functional configuration for performing the cleaning process using the semiconductor manufacturing apparatus 10 will be described. The control unit 30 includes a cleaning processing unit 31, a reactive gas concentration computation unit 32, and a process checkup unit 33.

The cleaning processing unit 31 includes a sealed cleaning processing unit 311 for executing a sealed cleaning process with respect to the chamber 11, a reactive gas evacuation unit 312 for evacuating the chamber 11 by exhausting the reactive gas after the sealed cleaning process, and a checkup cleaning processing unit 313 for executing a checkup cleaning process. The cleaning processing unit 31 is connected to each of the gas valves 14, 17, 18, and 19 and controls an open/close state of each of the gas valves 14, 17, 18, and 19 by a predefined program prepared beforehand during the sealed cleaning process, the evacuation process, and the checkup cleaning process.

The sealed cleaning processing unit 311 performs a sealed cleaning process by controlling an open/close state of the gas valves 14, 17, 18, and 19 to seal the cleaning gas inside the chamber 11 for a predetermined period of time. For example, when the sealed cleaning process is executed, the gas in the chamber 11 is sufficiently exhausted by closing the gas valve 14 and opening the gas valves 17 to 19. Then, the gas valve 14 of the pipe connected to the cleaning gas inlet unit is opened to supply the cleaning gas until the chamber 11 has a predetermined pressure. Then, if the chamber 11 has a predetermined pressure, the gas valve 14 is also closed. As such, the cleaning performed with the cleaning gas being sealed in the chamber 11 without exhausting the cleaning gas from the chamber 11 during the cleaning is referred to as sealed cleaning. During the sealed cleaning process, the cleaning gas reacts with the deposited film such as a film adhering to the inner surface of the chamber 11 to generate a reactive gas. Herein, since it is assumed that a silicon-based film is formed using the semiconductor manufacturing apparatus 10, SiF₄ is generated as the reactive gas.

The reactive gas evacuation unit 312 performs a process of evacuating the chamber 11 up to a predetermined vacuum degree after the sealed cleaning processing unit 311 completes the sealed cleaning process. As a result, the reactive gas and the unreacted cleaning gas are exhausted from the chamber 11. For example, control is performed such that the gas inside the chamber 11 is exhausted using a vacuum pump 16 by closing the gas valve 14 and opening the gas valves 17 to 19.

The checkup cleaning processing unit 313 performs a checkup cleaning process for checking whether the deposits in the chamber 11 are removed through the sealed cleaning process executed by the sealed cleaning processing unit 311. In the checkup cleaning process, the gas valve 14 is opened to allow the supply of the cleaning gas to the chamber 11, and the gas valves 17 to 19 are also opened. In addition, the gas valve 17 is adjusted so that the chamber 11 has a predetermined internal pressure. That is, similar to the cleaning of the related art, the checkup cleaning process is performed while the cleaning gas flows.

The reactive gas concentration computation unit 32 obtains a signal from the gas composition detection unit 20 during execution of the checkup cleaning process and computes the amount of the reactive gas contained in the gases (hereinafter, referred to as a reactive gas concentration). For example, when the gas composition detection unit 20 is an NDIR, the signal of the reactive gas output from the NDIR is obtained, and the reactive gas concentration in the gas is computed.

The process checkup unit 33 checks whether the reactive gas concentration computed using the reactive gas concentration computation unit 32 is equal to or lower than the reactive gas concentration (hereinafter, referred to as a deposit removal determination value) used to determine that the deposits in the chamber 11 are removed, in order to determine whether the deposits on the inner wall of the chamber 11 are removed. For example, when the reactive gas concentration is equal to or lower than the deposit removal determination value, it is determined that the deposits are removed from the chamber 11 by the sealed cleaning process. When the reactive gas concentration is larger than the deposit removal determination value, it is determined that the deposits remain in the chamber 11. In addition, when the reactive gas concentration is larger than the deposit removal determination value, the process checkup unit 33 instructs the sealed cleaning processing unit 311 to execute the sealed cleaning process.

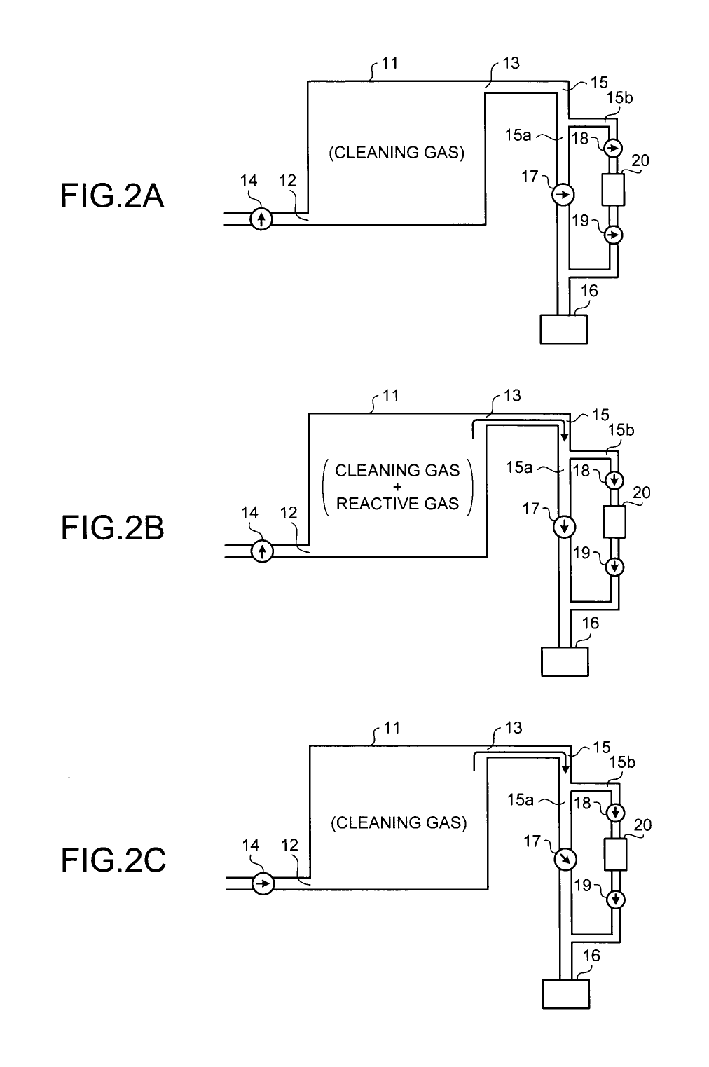

Next, the cleaning method of the semiconductor manufacturing apparatus according to the first embodiment will be described. FIGS. 2A to 2C are diagrams schematically illustrating an exemplary sequence of the cleaning method according to the first embodiment. For example, it is assumed that the semiconductor manufacturing apparatus 10 is a low pressure chemical vapor deposition (LP CVD) apparatus for forming a silicon-based thin-film. It is assumed that, for example, the cleaning process is performed after the silicon-based thin-film is manufactured on a predetermined number of wafers (substrates) using the semiconductor manufacturing apparatus 10.

First, after the chamber 11 is evacuated, the cleaning gas is introduced from the cleaning gas inlet unit into the chamber 11 by opening the gas valve 14 and closing the gas valves 17 to 19. As the cleaning gas, for example, a F₂ or ClF₃ gas is used. In addition, after a predetermined amount of the cleaning gas is introduced into the inside of the chamber 11, the gas valve 14 is closed (see FIG. 2A). As a result, the cleaning gas is sealed in the chamber 11.

This state is kept for a predetermined period of time. In the meantime, the cleaning gas reacts with the deposits adhering to the inner surface of the chamber 11 and as a result, a reactive gas is generated. After a predetermined time, the gas is exhausted from the chamber 11 (see FIG. 2B) by closing the gas valve 14 and opening the gas valve 17. In this case, the gas valves 18 and 19 may be opened or closed.

After the gas is sufficiently exhausted from the chamber 11, the gas valves 14, 18, and 19 are opened to supply the cleaning gas again into the chamber 11. In addition, the checkup cleaning process is performed for a predetermined period of time while the pressure in the chamber 11 is adjusted by adjusting the opening of the gas valve 17 (see FIG. 2C). In this case, a part of the gas exhausted from the chamber 11 passes through the pipe 15b provided with the gas composition detection unit 20, and the gas composition detection unit 20 detects a composition of the reactive gas contained in the exhaust gas, so that a measurement result thereof is output to the control unit 30. Here, since the silicon-based film adhering to the inner surface of the chamber 11 is removed using a F₂ or ClF₃ gas, the gas composition detection unit 20 is set to detect SiF₄ as the reactive gas. In addition, the checkup cleaning process may be performed for a period of time which is sufficient to detect the reactive gas contained in the exhaust gas, and the processing time for this checkup cleaning process is significantly shorter than that of the sealed cleaning process. For this reason, the amount of the cleaning gas used in the checkup cleaning process is small. In addition, the reactive gas concentration computation unit 32 computes the reactive gas concentration (amount) contained in the exhaust gas using the signal from the gas composition detection unit 20.

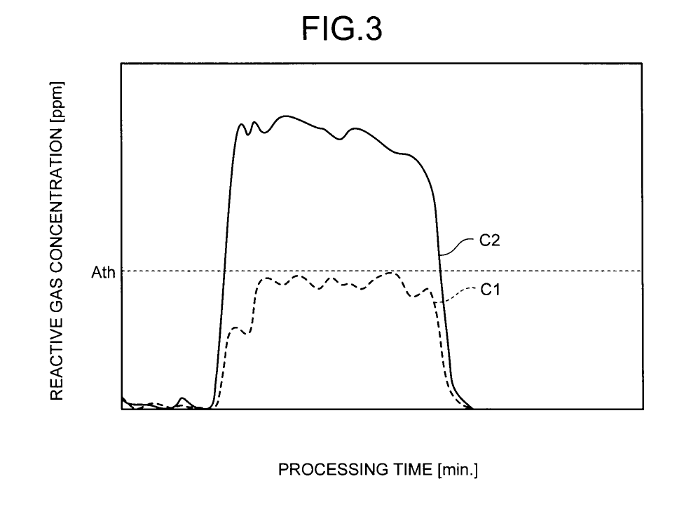

FIG. 3 is a diagram illustrating an exemplary reactive gas concentration contained in the exhaust gas. In FIG. 3, the abscissa indicates a processing time, and the ordinate indicates a reactive gas concentration. It shows that the checkup cleaning process is performed for a predetermined period of time (a short period of time, for example, several minutes). If the concentration of the reactive gas SiF₄ contained in the exhaust gas when the deposits in the chamber 11 can be removed through the sealed cleaning process is Ath (ppm) as illustrated in the curve C1, it can be determined that the sealed cleaning process is normally terminated. If such a concentration is higher than Ath (ppm) as illustrated in the curve C2, it can be determined that the deposits cannot be removed from the chamber 11 through the sealed cleaning process. That is, in this case, it is assumed that Ath (ppm) is used as the deposit removal determination value.

The process checkup unit 33 determines that the sealed cleaning process is not terminated when the reactive gas concentration computed by the reactive gas concentration computation unit 32 is higher than Ath (ppm), and hence the process checkup unit 33 instructs the sealed cleaning processing unit 311 to execute the sealed cleaning process again, so that the processes starting from FIG. 2A are performed. On the other hand, when the reactive gas concentration computed by the reactive gas concentration computation unit 32 is equal to or lower than Ath (ppm), it is determined that the sealed cleaning process is normally stopped, and the cleaning process is finished.

According to the first embodiment, the checkup cleaning process is performed by sealing the cleaning gas in the chamber 11, executing the sealed cleaning process for a predetermined period of time, exhausting the gas from the chamber 11, flowing the cleaning gas into the chamber 11, and detecting the concentration of the reactive gas contained in the exhaust gas using the gas composition detection unit 20 while the pressure is being adjusted. As a result, the cleaning gas used in the cleaning inside the chamber 11 can be remarkably reduced in comparison with a cleaning technique of the related art in which the process is performed while the gas valves 17 to 19 are opened. In addition, the time for the checkup cleaning process may be sufficient if the presence of the reactive gas can be sensed for that time. Therefore, it is possible to reduce the cleaning gas amount used in the checkup cleaning process to a requisite minimum. Accordingly, it is possible to suppress wasteful use of the cleaning gas. Furthermore, the checkup cleaning process is advantageous also in the point that it is possible to check whether the deposits present in the chamber 11.

### Second Embodiment

In the first embodiment, whether deposits present in the chamber is checked through the checkup cleaning process by exhausting the gas from the chamber after the sealed cleaning process is performed. In a second embodiment, a semiconductor manufacturing apparatus and a cleaning method thereof capable of rapidly performing a process checkup in comparison with the first embodiment will be described.

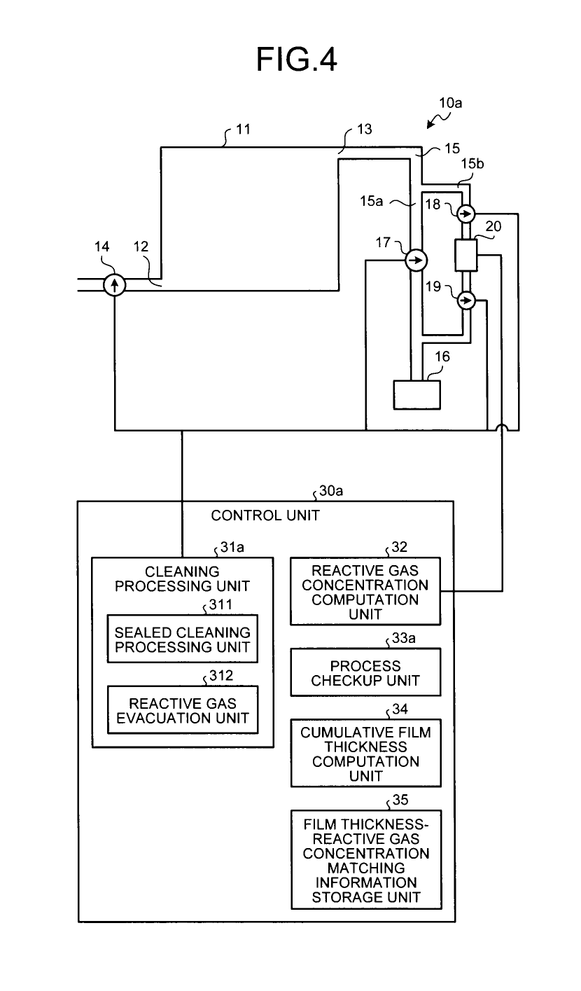

FIG. 4 is a diagram schematically illustrating an exemplary configuration of the semiconductor manufacturing apparatus according to the second embodiment. A semiconductor manufacturing apparatus 10a is different from the semiconductor manufacturing apparatus 10 of the first embodiment in that the checkup cleaning processing unit 313 of the cleaning processing unit 31a is not provided, but a cumulative film thickness computation unit 34 and a film thickness-reactive gas concentration matching information storage unit 35 are provided in the control unit 30a instead.

The cumulative film thickness computation unit 34 computes a cumulative film thickness as an adherence amount of the film adhering to the inner wall of the chamber 11 during a period between the end of a sealed cleaning process and the start of a next sealed cleaning process. The cumulative film thickness can be computed by obtaining the film thickness, for example, formed on the wafer through the film formation process performed using a film formation unit (not illustrated) of the control unit 30a until before the next sealed cleaning process and summing the obtained film thicknesses. The cumulative film thickness computation unit 34 resets the cumulative film thickness after the sealed cleaning process is performed. In addition, the film thickness on the wafer may be used as the film thickness, or an actual film thickness deposited on the inner wall of the chamber 11 may be used as the film thickness.

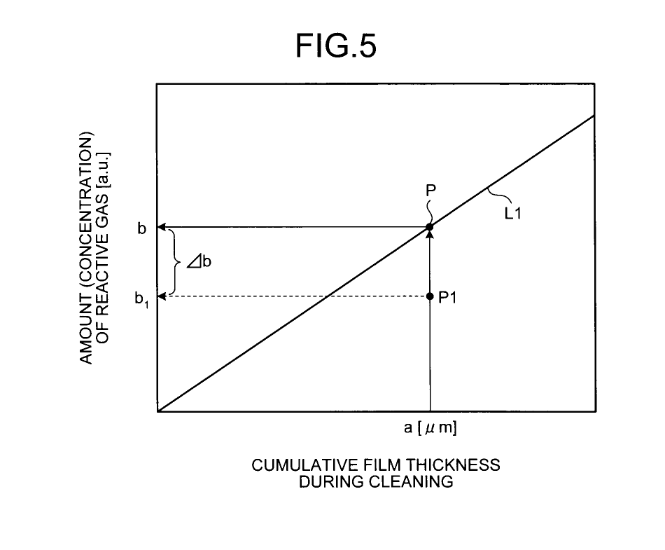

The film thickness-reactive gas concentration matching information storage unit 35 stores film thickness-reactive gas concentration matching information indicating a relation between the cumulative film thickness of the deposits in the chamber 11 and the reactive gas concentration in the chamber 11 obtained when the deposits are removed. FIG. 5 is a diagram illustrating exemplary film thickness-reactive gas concentration matching information. In FIG. 5, the abscissa indicates the cumulative film thickness in the chamber 11 when the sealed cleaning process is initiated, and the ordinate indicates a reactive gas amount (concentration) in the chamber 11. In addition, the straight line L1 indicates the reactive gas amount (concentration) contained in the cleaning gas when the deposits in the chamber 11 are perfectly removed from the chamber 11 for each film thickness.

Similar to the first embodiment, the process checkup unit 33a is provided to check whether the deposits remain in the chamber 11 after the sealed cleaning process. However, unlike the first embodiment, the process checkup is not performed by comparing the value computed by the reactive gas concentration computation unit 32 with the deposit removal determination value, but is performed using the relation between the cumulative film thickness during the sealed cleaning process and the reactive gas concentration after the sealed cleaning process. Specifically, the process checkup unit 33a performs the process checkup by computing the reactive gas concentration (hereinafter, referred to as an estimated reactive gas concentration) corresponding to the cumulative film thickness of the deposits in the chamber 11 obtained from the cumulative film thickness computation unit 34, when the sealed cleaning process is initiated, based on the film thickness-reactive gas concentration matching information, and comparing the reactive gas concentration (hereinafter, referred to as an actual reactive gas concentration) contained in the gas in the chamber 11 obtained from the reactive gas concentration computation unit 32 during the evacuation process with the estimated reactive gas concentration.

For example, in a case where the cumulative film thickness in the chamber 11 during the sealed cleaning process is a (μm), the process checkup unit 33a obtains the estimated reactive gas concentration b from FIG. 5. In addition, the actual reactive gas concentration is obtained from the reactive gas concentration computation unit 32 during the evacuation process following the sealed cleaning process, and compared with the estimated reactive gas concentration b. In a case where the actual reactive gas concentration is equal to b, it is determined that the actual reactive gas concentration agrees with the estimated reactive gas concentration b, the deposits corresponding to the cumulative film thickness a (μm) are removed, and the sealed cleaning is completed. Accordingly, the process advances to, for example, the following film formation process. Meanwhile, in a case where the reactive gas concentration is b1 (<b), it means that reaction is not progressed for the amount as much as b−b1=Δb. Therefore, the process checkup unit 33a determines that the sealed cleaning process is continued with the cleaning gas further added or in a state as it is. In this case, a relation between a value Δb indicating a degree of reaction delay and a condition of the sealed cleaning process (such as the introduced gas amount or the sealed cleaning process time) may be experimentally obtained in advance, and the additional condition of the sealed cleaning process may be automatically computed based on the value Δb. In the following description, like reference numerals denote like elements as in the first embodiment, and description thereof will not be repeated.

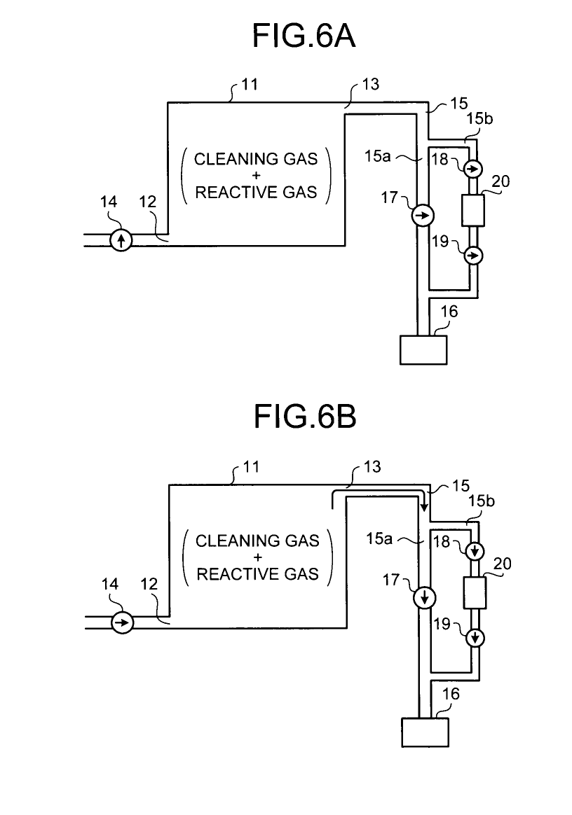

Next, a cleaning method of the semiconductor manufacturing apparatus according to the second embodiment will be described. FIGS. 6A and 6B are diagrams schematically illustrating an exemplary sequence of the cleaning method according to the second embodiment. Similar to the first embodiment, a case where the silicon-based thin film is formed using a low pressure chemical vapor deposition (LP CVD) apparatus as a semiconductor manufacturing apparatus 10a will be exemplarily described.

The cumulative film thickness computation unit 34 of the control unit 30a computes the cumulative film thickness formed during a period until a film forming process by the LP CVD apparatus is completed, that is, a period from after the previous sealed cleaning process to the current time. The cumulative film thickness computation unit 34 transmits the computed cumulative film thickness to the process checkup unit 33a. After the film formation process is terminated, and the chamber 11 is evacuated as illustrated in FIG. 2A, a predetermined amount of the cleaning gas such as a F₂ or ClF₃ gas is introduced into the chamber 11 from the cleaning gas inlet unit by opening the gas valve 14 and closing the gas valves 17 to 19. Then, the gas valve 14 is closed (FIG. 6A). As a result, the cleaning gas is sealed in the chamber 11. This state is left unchanged for a predetermined period of time, so that the cleaning gas reacts with the deposits in the chamber 11 to generate the reactive gas.

After a predetermined period of time, the amount (concentration) of the reactive gas contained in the exhausted gas is measured (FIG. 6B) while the gas in the chamber 11 is exhausted by opening the gas valves 17 to 19 and closing the gas valve 14 (FIG. 6B). In this case, the gas valve 17 may be opened or closed.

In the evacuation process, the reactive gas concentration computation unit 32 transmits the reactive gas concentration in the chamber 11 to the process checkup unit 33a, and the process checkup unit 33a stores the reactive gas concentration as an actual reactive gas concentration. In addition, the process checkup unit 33a obtains the estimated reactive gas concentration corresponding to the cumulative film thickness which is obtained by the cumulative film thickness computation unit 34 from the film thickness-reactive gas concentration matching information in the film thickness-reactive gas concentration matching information storage unit 35, and determines whether the actual reactive gas concentration is equal to or lower than the estimated reactive gas concentration.

If the actual reactive gas concentration is lower than the estimated reactive gas concentration, it is determined that the deposits in the chamber 11 are not removed. Therefore, the sealed cleaning process is executed again after the evacuation process is terminated. If the actual reactive gas concentration is equal to the estimated reactive gas concentration, it is determined that the deposits in the chamber 11 are removed. Therefore, the evacuation process is terminated, and the sealed cleaning process is terminated.

In the second embodiment, the cumulative film thickness of the film deposited in the chamber 11 and the reactive gas concentration of the gas in the chamber 11 of the case where the film is removed are stored in advance as the film thickness-reactive gas concentration matching information. In addition, setting is made to detect the actual reactive gas concentration of the exhaust gas during the gas evacuation process for the gas remaining in the chamber 11 after the sealed cleaning process is performed. As a result, it is possible to perform a process checkup regarding whether the deposits in the chamber 11 are removed by comparing the actual reactive gas concentration with the estimated reactive gas concentration obtained using the film thickness-reactive gas concentration matching information from the cumulative film thickness in the chamber 11 when the sealed cleaning process is initiated.

In the second embodiment, since the reactive gas concentration is detected during the evacuation process of the gas in the chamber 11 which follows the sealed cleaning process, it is possible to rapidly perform the process checkup in comparison with the first embodiment. In addition, it is possible to reduce the cleaning gas consumptions.

### Third Embodiment

In the process checkup according to the first and second embodiments, checkup is made only for whether the deposits remain in the chamber. In the third embodiment, a semiconductor manufacturing apparatus and a cleaning method thereof capable of sensing the end point of the sealed cleaning process will be described.

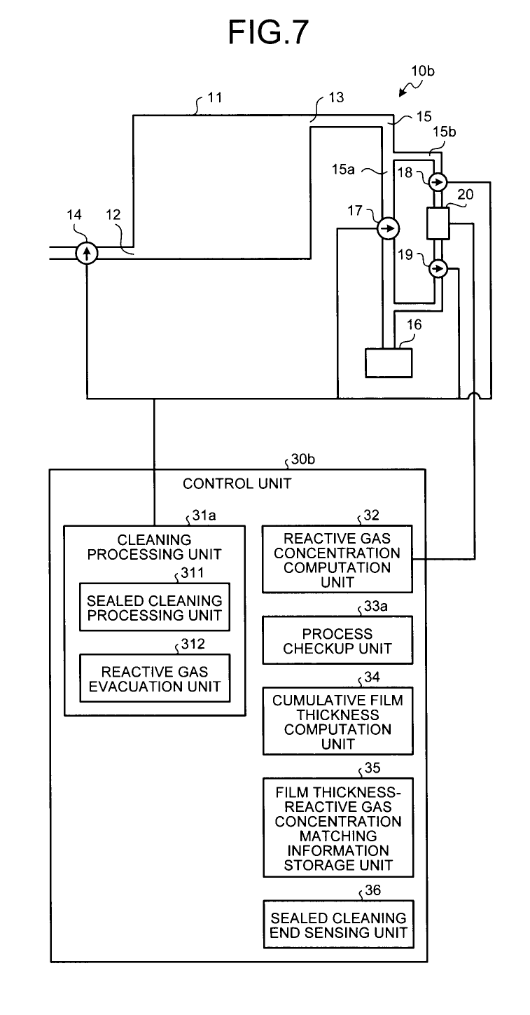

FIG. 7 is a diagram schematically illustrating an exemplary configuration of the semiconductor manufacturing apparatus according to the third embodiment. The semiconductor manufacturing apparatus 10b is different from the semiconductor manufacturing apparatus 10a of the second embodiment in that the sealed cleaning end sensing unit 36 is provided in the control unit 30b. The sealed cleaning end sensing unit 36 monitors the reactive gas concentration in the chamber 11 during the sealed cleaning process, detects the time point at which the etching of deposits is terminated, and notifies the cleaning processing unit 31a of the termination of the sealed cleaning process. In addition, the sealed cleaning end sensing unit 36 also senses a case where the cleaning gas amount is small relative to the deposit amount, and the cleaning gas is used up. In this case, the cleaning processing unit 31a is instructed to execute the sealed cleaning process again. In the following description, like reference numerals denote like elements as in the first and second embodiments, and description thereof will not be repeated.

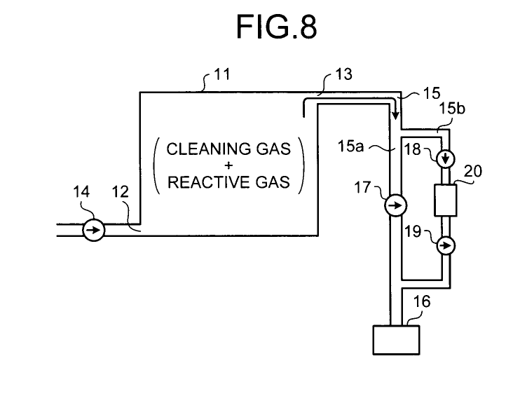

Next, a cleaning method of the semiconductor manufacturing apparatus according to the third embodiment will be described. FIG. 8 is a diagram schematically illustrating an exemplary sequence of the cleaning method according to the third embodiment. Similar to the first embodiment, a case where the LP CVD apparatus in which the inner wall of the chamber 11 and the like are made of quartz is used as the semiconductor manufacturing apparatus 10b to form a silicon-based thin film will be exemplarily described.

The cumulative film thickness computation unit 34 of the control unit 30b computes the cumulative film thickness accumulated until now after the entire sealed cleaning process is executed, before the film formation process in the LP CVD apparatus is terminated. The cumulative film thickness computation unit 34 transmits the computed cumulative film thickness to the process checkup unit 33a. After the film formation process is terminated, and the chamber 11 is evacuated, a predetermined amount of the cleaning gas such as a F₂ or ClF₃ gas is introduced into the chamber 11 from the cleaning gas inlet unit by opening the gas valves 14 and 18 and closing the gas valves 17 and 19. Then, the gas valve 14 is closed (FIG. 8). As a result, the cleaning gas is sealed in the chamber 11. The present embodiment is different from the first and second embodiments in that the gas valve 18 is opened, and the gas valve 19 is closed, so that the gas composition detection unit 20 can detect the reactive gas during the sealed cleaning process. In addition, it is assumed that the sealed cleaning process for performing etching of the silicon-based film as the deposits is carried out using a certain selectivity with quartz.

If this state is left unchanged for a predetermined time period, the cleaning gas reacts with the deposits in the chamber 11 to generate the reactive gas. The generated reactive gas is dispersed in the chamber 11 and the pipe 15 (15a and 15b). Therefore, the change of the reactive gas amount in the chamber 11 is detected by the gas composition detection unit 20 provided in the pipe 15b. The reactive gas concentration computation unit 32 computes the actual reactive gas concentration using the signal from the gas composition detection unit 20 at that time point, transmits the actual reactive gas concentration to the process checkup unit 33a, and transmits the actual reactive gas concentration to the sealed cleaning end sensing unit 36 along with time information.

As described in conjunction with the second embodiment, the process checkup unit 33a performs the process checkup based on comparison between the actual reactive gas concentration obtained from the reactive gas concentration computation unit 32 and the estimated reactive gas concentration obtained using the film thickness-reactive gas concentration matching information from the cumulative film thickness during the sealed cleaning process.

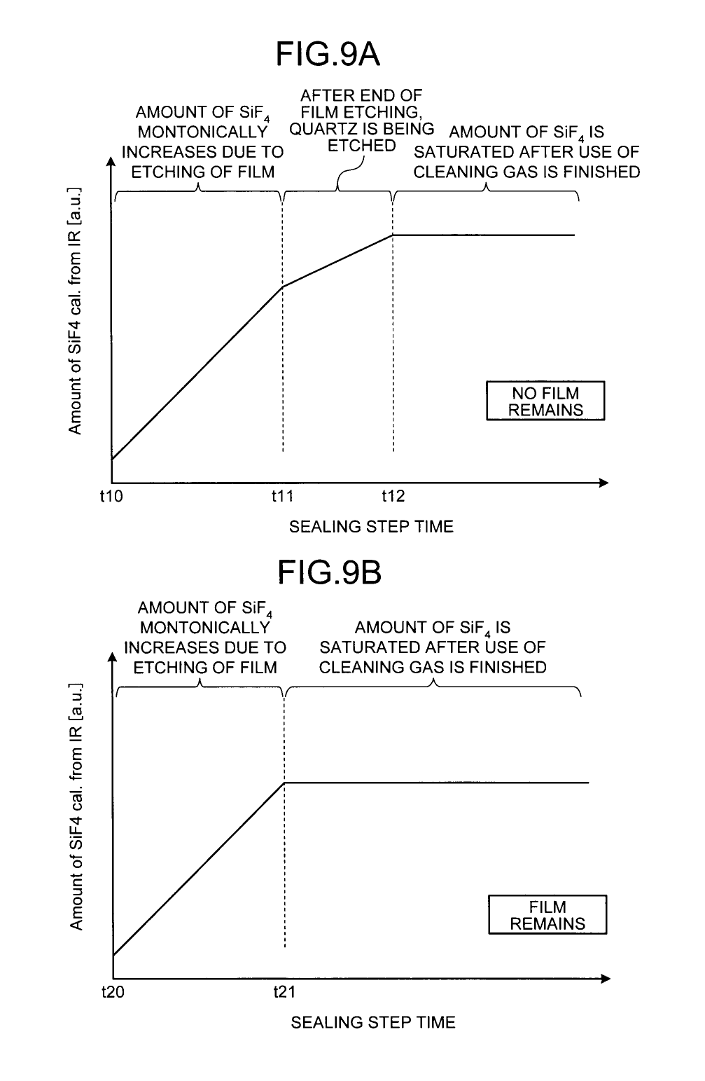

In addition, the sealed cleaning end sensing unit 36 accumulates time information and the actual reactive gas concentration obtained from the reactive gas concentration computation unit 32 as the actual reactive gas concentration-time information. FIGS. 9A and 9B are diagrams illustrating exemplary actual reactive gas concentration-time information. FIG. 9A is a diagram illustrating an exemplary case where the amount of the cleaning gas is larger than the amount capable of removing the deposits from the chamber 11. FIG. 9B is a diagram illustrating an exemplary case where the amount of the cleaning gas is smaller than the amount capable of perfectly removing the deposits from the chamber 11. In FIGS. 9A and 9B, the abscissa indicates a sealing time, and the ordinate indicates a reactive gas amount (concentration) in the chamber.

When the amount of the cleaning gas is larger than the amount capable of removing deposits from the chamber:

Initially, as time elapses, the concentration of the reactive gas (SiF₄) in the chamber 11 monotonically increases. That is, as illustrated as the time points t10 and t11 in FIG. 9A, the reactive gas concentration linearly increases as time elapses. If the etching of deposits in the chamber 11 is completed, then the cleaning gas starts to etch elements in the chamber 11. Herein, since the inner wall of the chamber 11 is made of quartz, the quartz is etched, and SiF₄ as the reactive gas is generated similar to the deposits. However, since the etching of deposits is carried out using a selectivity with quartz, the etching rate is abruptly reduced after the etching of elements in the chamber 11 is initiated. As a result, as illustrated in the time points t11 to t12 of FIG. 9A, it is possible to obtain a straight line having an inclination smaller than the inclination at the time of etching of the deposits. Then, when the cleaning gas is perfectly used up, the reaction in the chamber 11 does not further progress, and the reactive gas concentration becomes constant (saturated). In this case, as illustrated in the time point t12 and subsequent time points of FIG. 9A, it is possible to obtain a straight line having an inclination of zero.

In a case where the actual reactive gas concentration-time information exhibits such a behavior, the inclination of the straight line is changed when the etching of the deposits in the chamber 11 is terminated and the etching of quartz of the element in the chamber 11 is initiated. That is, if the time-dependent curve of the actual reactive gas concentration is differentiated against time, it can be determined that the sealed cleaning process is terminated when the differential value is changed. In this regard, the sealed cleaning end sensing unit 36 obtains the differential value against time for the actual reactive gas concentration using the accumulated actual reactive gas concentration-time information, detects an inflection point of the differential value as the end point of the sealed cleaning process, and notifies the cleaning processing unit 31a of a signal indicating that the sealed cleaning process is terminated. As the cleaning processing unit 31a receives that signal, the cleaning processing unit 31a evacuates the chamber 11, and the sealed cleaning process is terminated.

When the amount of the cleaning gas is equal to or smaller than the amount capable of perfectly removing deposits:

Initially, as time elapses, the reactive gas concentration (amount) in the chamber 11 monotonically increases. That is, as illustrated in the time points t20 to t21 of FIG. 9B, the reactive gas concentration linearly increases as time elapses. However, if the deposits in the chamber 11 still remain, and the cleaning gas is perfectly used up, the reaction in the chamber 11 does not further progress, and the amount of the reactive gas becomes constant (saturated). In this case, as illustrated in the time point t21 and subsequent time points in FIG. 9B, the straight line has an inclination of zero.

In a case where the actual reactive gas concentration-time information exhibits such a behavior, it is determined that the cleaning gas is perfectly used up during the etching of deposits in the chamber 11. That is, if the time-dependent curve of the actual reactive gas is differentiated against time, it can be determined that the amount of the cleaning gas is short when the differential value changes from a positive value to zero. In this regard, the sealed cleaning end sensing unit 36 obtains the differential value against time for the actual reactive gas concentration using the accumulated actual reactive gas concentration-time information, and detects the point where the differential value is changed to zero as an indication of the state that the cleaning gas is perfectly used up before the deposits are removed from the chamber 11. In addition, the sealed cleaning end sensing unit 36 instructs the cleaning processing unit 31a to perform the sealed cleaning process again.

In addition, the change of the differential value may be detected considering an error of the computed reactive gas concentration. For example, it may be determined that the differential value is changed when the differential value is changed over a predetermined range in comparison with the differential values computed in the past, or when differential values different from those computed in the past are successively obtained for a predetermined number of times.

According to the third embodiment, the actual reactive gas concentrations at each time point are accumulated, and the sealed cleaning end sensing unit 36 detects the time point when the differential value of the actual reactive gas concentration against time is changed. When the differential value is changed from a positive value into a non-zero positive value smaller than that value, it is determined that the sealed cleaning process is terminated. When the differential value becomes zero, it is determined that it is difficult to remove the deposits from the chamber 11 due to a shortage of the cleaning gas. As a result, it is possible to stop the etching process at the same time point when the etching of the deposits adhered in the chamber 11 is terminated. Therefore, it is possible to prevent a material of the chamber 11 from being excessively etched beyond necessity.

In addition, since a case where the cleaning gas is used up before the deposits in the chamber 11 are perfectly removed can be rapidly detected, it is possible to rapidly perform the sealed cleaning process again. For example, according to the second embodiment, the sealed cleaning process is performed, and the process checkup is performed after a predetermined time. If it is determined that the deposits in the chamber 11 still remain, the sealed cleaning process is performed again. However, according to the third embodiment, it is possible to perform the sealed cleaning process again even when the cleaning gas is used up. Therefore, it is possible to reduce unnecessary time consumption in the sealed cleaning process.

According to the embodiments described above, a LP CVD apparatus has been exemplified as the semiconductor manufacturing apparatus. However, the aforementioned embodiments may be applied to an apparatus, in which a cleaning process is necessary, such as a dry etching apparatus as the semiconductor manufacturing apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cleaning method of a semiconductor manufacturing apparatus, the method comprising:
sealing a cleaning gas in a chamber of the semiconductor manufacturing apparatus;
generating a reactive gas by reacting the cleaning gas with deposits adhered in the chamber;
exhausting the gas from the chamber after a predetermined time;
introducing and exhausting the cleaning gas into and from the chamber to maintain a pressure inside the chamber in a predetermined value;
measuring the reactive gas concentration contained in the exhausted gas; and
determining whether the cleaning is terminated by comparing the reactive gas concentration with a determination value obtained when the deposits in the chamber are removed.

2. The cleaning method according to claim 1, wherein in the determining termination of the cleaning, it is determined that the deposits inside the chamber are removed when the reactive gas concentration is equal to or lower than a determination value.

3. The cleaning method according to claim 1, wherein, in the determining termination of the cleaning, when the reactive gas concentration is higher than the determination value, it is determined that the deposits remain in the chamber.

4. The cleaning method according to claim 3, wherein, when it is determined that the deposits remain in the chamber, the process of sealing the cleaning gas to the process of determining termination of the cleaning are executed again.

5. The cleaning method according to claim 1, wherein the cleaning gas is a halogen-based gas, and the reactive gas is SiH₄.

6. The cleaning method according to claim 1, wherein in the measuring the reactive gas concentration, a non-dispersive infrared analysis device or a gas mass flow sensor is used.

7. A semiconductor manufacturing apparatus comprising:
a chamber;
a cleaning gas inlet unit that supplies a cleaning gas to the chamber through a first pipe;
an evacuation unit that evacuates the chamber through a second pipe;
a gas composition detection unit provided in the second pipe to detect a gas composition flowing through the second pipe;
first and second gas valves provided in the first and second pipes, respectively; and
a control unit that controls an open/close state of the first and second gas valves,
wherein the control unit includes:
a cleaning processing unit that controls an open/close state of the first and second valves to perform an sealed cleaning process for sealing the cleaning gas from the cleaning gas inlet unit in the chamber, an evacuation process for exhausting a gas from the chamber after the sealed cleaning process is terminated, and a checkup cleaning process for checking whether deposits is removed from the chamber while the cleaning gas flows into the chamber after the evacuation process is terminated;
a reactive gas concentration computation unit that computes a reactive gas concentration generated by reaction between the cleaning gas and the deposits adhered in the chamber up of the gas flowing through the second pipe based on a signal from the gas composition detection unit during the checkup cleaning process; and
a process checkup unit that compares the reactive gas concentration computed by the reactive gas concentration computation unit with a determination value obtained when the deposits in the chamber are removed in order to check whether the deposits are removed from the chamber.

8. The semiconductor manufacturing apparatus according to claim 7, wherein the process checkup unit determines that the deposits are removed from the chamber when the reactive gas concentration is equal to or lower than the determination value.

9. The semiconductor manufacturing apparatus according to claim 7, wherein the process checkup unit determines that the deposits in the chamber remain when the reactive gas concentration is higher than the determination value.

10. The semiconductor manufacturing apparatus according to claim 9, wherein, when the process checkup unit determines that the deposits in the chamber remain, the cleaning processing unit controls an open/close state of the first and second gas valves such that the sealed cleaning process to the checkup cleaning process are executed.

11. The semiconductor manufacturing apparatus according to claim 7, wherein the cleaning gas is a halogen-based gas, and the gas composition detection unit detects SiH₄ as the gas composition.

12. The semiconductor manufacturing apparatus according to claim 7, wherein the gas composition detection unit is a non-dispersive infrared analysis device or a gas mass flow sensor.
